(19) United States
(12) Patent Application Publication
(10) Pub. No.: US 2014/0360871 A1
(43) Pub. Date: Dec. 11, 2014

(54) Fe-Pt-Ag-C-Based Sputtering Target Having C Grains Dispersed Therein, and Method for Producing Same

(71) Applicant: JX Nippon Mining & Metals Corporation, Tokyo (JP)

(72) Inventors: Atsushi Sato, Ibaraki (JP); Hideo Takami, Ibaraki (JP)

(21) Appl. No.: 14/372,849

(22) PCT Filed: Apr. 10, 2013
(86) PCT No.: PCT/JP2013/060812

§ 371 Date: Jul. 17, 2014

(30) Foreign Application Priority Data
May 22, 2012 (JP) 2012-116813

(51) Int. Cl. H01J 37/34; B22F 3/10

(52) U.S. Cl. CPC H01J 37/3429; B22F 3/10; B22F 2301/00; B22F 2302/40
USPC 204/298.13; 419/11

(57) ABSTRACT

An Fe—Pt—Ag—C-based sintered compact sputtering target having a composition represented by a formula (Fe_{100-X}—Pt_{X})_{100-Y-Z}—Ag_{Y}-C_{Z} (wherein X represents a numerical value satisfying a formula 35≦X≦55; Y represents a numerical value satisfying a formula 0.5≦Y≦15; and Z represents a numerical value satisfying a formula 15≦Z≦55) when expressed in an atomic ratio, and having a relative density of 93% or more. A method for producing an Fe—Pt—Ag—C-based sintered compact sputtering target, characterized in that an Fe—Pt—C sintered compact is produced in advance, the sintered compact is pulverized to produce a pulverized powder, the pulverized powder is mixed with a Ag powder, and the resultant mixed powder is subject to sintering at a temperature lower than a melting point of Ag. An object of this invention is to provide a high-density sputtering target which enables the production of a magnetic thin film having a granular structure without the use of expensive co-sputtering equipment and which enables the reduction in the amount of particles generated during sputtering.

### TECHNICAL FIELD

The present invention relates to a sputtering target for use in the deposition of a granular-type magnetic thin film in a thermally assisted magnetic recording medium, and particularly relates to an Fe—Pt—Ag—C-based sputtering target having C grains dispersed therein, and a method for producing such an Fe—Pt—Ag—C-based sputtering target.

### BACKGROUND ART

In the field of magnetic recording as represented with hard disk drives, a material that is based on a ferromagnetic metal such as Co, Fe, or Ni is being used as the material of a magnetic thin film in a magnetic recording medium. For example, a Co—Cr-based or a Co—Cr—Pt-based ferromagnetic alloy having Co as its main component has been used for the magnetic thin film of a hard disk that adopts the longitudinal magnetic recording system.

Moreover, a composite material made from a Co—Cr—Pt-based ferromagnetic alloy having Co as its main component and nonmagnetic inorganic grains is often used for the magnetic thin film of a hard disk that adopts the perpendicular magnetic recording system which has been put into practical use in recent years. In addition, these magnetic thin films are often produced by sputtering a target made from the foregoing materials using DC magnetron sputtering equipment in light of its high productivity.

Meanwhile, the recording density of hard disks is rapidly increasing year by year, and the current surface density of 600 Gbit/in² is expected to reach 1 Tbit/in² in the future. When the recording density reaches 1 Tbit/in², the size of the recording bit will fall below 10 nm. In such a case, it is anticipated that the superparamagnetism caused by thermal fluctuation will become a problem, and it is further anticipated that the currently used materials of a magnetic recording medium; for instance, a material with higher magnetic crystalline anisotropy obtained by adding Pt to a Co—Cr-based alloy, will no longer be sufficient. This is because magnetic grains to stably behave as a ferromagnetic at a size of 10 nm or less need to possess even higher magnetic crystalline anisotropy.

Based on the reasons described above, an FePt phase having an L1₀ structure is attracting attention as a material for use in an ultrahigh-density recording medium. Since an FePt phase having a L1₀ structure yields superior corrosion resistance and oxidation resistance in addition to having high magnetic crystalline anisotropy, it is expected to become a material that can be suitably applied as a magnetic recording medium.

Furthermore, in connection with using the FePt phase as a material for use in an ultrahigh-density recording medium, demanded is the development of technology for dispersing the ordered FePt magnetic grains, in a magnetically isolated state, while densely aligning the orientation thereof as much as possible.

In light of the foregoing circumstances, a magnetic thin film having a granular structure in which the FePt magnetic grains having an L1₀ structure are isolated from nonmagnetic materials such as oxides and carbon is being proposed for use in a magnetic recording medium of next-generation hard disks adopting the thermally assisted magnetic recording system. This magnetic thin film having a granular structure has a structure in which the magnetic grains are magnetically insulated through the interposition of nonmagnetic substances.

Documents related to a magnetic recording medium including a magnetic thin film having a granular structure and other related publications include, for example, Patent Document 1, Patent Document 2, Patent Document 3, Patent Document 4, and Patent Document 5 listed below.

As a magnetic thin film having a granular structure including the foregoing FePt phase having an L1₀ structure, a magnetic thin film containing C as a nonmagnetic substance in a volume ratio of 10 to 50% is particularly drawing attention from the level of its magnetic properties. It is known that this kind of magnetic thin film having a granular structure can be produced by co-sputtering an Fe target, a Pt target, and a C target, or co-sputtering an Fe—Pt alloy target, and a C target. Nevertheless, expensive co-sputtering equipment is required for co-sputtering these sputtering targets.

Moreover, generally speaking, when attempting to sputter a target, in which a nonmagnetic material is contained in an alloy, with sputtering equipment, there is a problem in that the nonmagnetic material will inadvertently become desorbed during sputtering or abnormal discharge will occur with the holes contained in the sputtering target as the starting point and consequently generate particles (contaminants that adhere to the substrate surface). In order to resolve this problem, it is necessary to increase the adhesion between the nonmagnetic material and the base alloy, and achieve higher densification of the sputtering target.

Generally speaking, a sputtering target material in which a nonmagnetic material is contained in an alloy is produced via the powder sintering method. However, when a large amount of C is contained in the Fe—Pt-based material, it is difficult to obtain a high-density sintered compact since C is a sintering-resistant material, and in particular it was not possible to produce an Fe—Pt—Ag—C-based sintered compact sputtering target having C grains dispersed therein and having a relative density of 93% or more.

By way of reference, Patent Documents 1 to 7 pertaining to a sputtering target for use in a recording medium using an Fe—Pt-based material are listed below.

### Patent Document 1: Patent Publication JP-A-2000-306228

### Patent Document 2: Patent Publication JP-A-2000-311329

### Patent Document 3: Patent Publication JP-A-2008-59733

### Patent Document 4: Patent Publication JP-A-2008-169464

### Patent Document 5: Patent Publication JP-A-2004-152471

### Patent Document 6: Patent Publication JP-A-2003-313659

### Patent Document 7: Patent Publication JP-A-2011-210291

### DISCLOSURE OF INVENTION

### Technical Problem

An object of this invention is to provide an Fe—Pt—Ag—C-based sputtering target having C grains dispersed therein which enables the production of a magnetic thin film having a granular structure without the use of expensive co-sputtering equipment, and a method for producing the same, and to additionally provide a high-density sputtering target which enables the reduction in the amount of particles generated during sputtering.

### Technical Solution

In order to achieve the foregoing object, as a result of intense study, the present inventors discovered that it is possible to uniformly disperse fine C grains, which are a nonmagnetic material, in a base metal, and produce a high-density sputtering target even upon containing Ag. The sputtering target produced as described above can dramatically reduce the generation of particles. In other words, the present inventors discovered a way of improving the deposition yield.

Based on the foregoing discovery, the present invention provides:

1) An Fe—Pt—Ag—C-based sintered compact sputtering target having a composition represented by a formula (Fe_{100-X}—Pt_{X})_{100-Y-Z}—Ag_{Y}—C_{Z} (wherein X represents a numerical value satisfying a formula 35≦X≦55; Y represents a numerical value satisfying a formula 0.5≦Y≦15; and Z represents a numerical value satisfying a formula 15≦Z≦55) when expressed in an atomic ratio, and having a relative density of 93% or more;
2) The Fe—Pt—Ag—C-based sintered compact sputtering target according to 1) above, wherein the Fe—Pt—Ag—C-based sintered compact sputtering target has a texture where an Fe—Pt—C phase, in which C is dispersed in an Fe—Pt alloy, and a Ag phase, mutually coexist;
3) The Fe—Pt—Ag—C-based sintered compact sputtering target according to 1) above, wherein the Fe—Pt—Ag—C-based sintered compact sputtering target has a texture where an Fe—Pt—C phase, in which C is dispersed in an Fe—Pt alloy, and a Ag—C phase, in which C is dispersed in Ag, mutually coexist; and
4) The Fe—Pt—Ag—C-based sintered compact sputtering target according to 1) above, wherein the Fe—Pt—Ag—C-based sintered compact sputtering target has a texture where an Fe—Pt—C phase, in which C is dispersed in an Fe—Pt alloy, a Ag phase, and a Ag—C phase, in which C is dispersed in Ag, mutually coexist.

The present invention additionally provides:

5) A method for producing an Fe—Pt—Ag—C-based sintered compact sputtering target, characterized in that an Fe—Pt—C sintered compact is produced in advance, the sintered compact is pulverized to produce a pulverized powder, the pulverized powder is mixed with a Ag powder, and the resultant mixed powder is subject to sintering at a temperature lower than a melting point of Ag;
6) A method for producing the Fe—Pt—Ag—C-based sintered compact sputtering target according to 1) or 2) above, characterized in that an Fe—Pt—C sintered compact is produced in advance, the sintered compact is pulverized to produce a pulverized powder, the pulverized powder is mixed with a Ag powder, and the resultant mixed powder is subject to sintering at a temperature lower than a melting point of Ag;
7) A method for producing an Fe—Pt—Ag—C-based sintered compact sputtering target, characterized in that an Fe—Pt—C sintered compact is produced in advance, the sintered compact is pulverized to produce a pulverized powder, the pulverized powder is mixed with a Ag powder and a C powder, and the resultant mixed powder is subject to sintering at a temperature lower than a melting point of Ag;
8) A method for producing the Fe—Pt—Ag—C-based sintered compact sputtering target according to any one of 1), 3) and 4) above, characterized in that an Fe—Pt—C sintered compact is produced in advance, the sintered compact is pulverized to produce a pulverized powder, the pulverized powder is mixed with a Ag powder and a C powder, and the resultant mixed powder is subject to sintering at a temperature lower than a melting point of Ag; and
9) The method for producing an Fe—Pt—Ag—C-based sintered compact sputtering target according to any one of 5) to 8) above, characterized in that a pulverized powder of an Fe—Pt—C sintered compact having a relative density of 93% or more is subject to mixing and sintering.

### Advantageous Effects of Invention

The Fe—Pt-based sputtering target, in which C grains are dispersed, according to the present invention enables the deposition of a magnetic thin film having a granular structure without the use of expensive co-sputtering equipment, and the present invention yields a superior effect of being able to provide a high-density sputtering target which can reduce the amount of particles generated during sputtering.

### BRIEF DESCRIPTION OF DRAWINGS

FIG. 1 This is a secondary electron image and an element distribution image upon observing the polished surface of the sputtering target (this hereinafter refers to the “vertical section of the sputter surface”) of Example 1 via EPMA. The whitish portion is where many of the relevant elements exist.

### DESCRIPTION OF EMBODIMENTS

The Fe—Pt—Ag—C-based sintered compact sputtering target having C grains dispersed therein according to the present invention is an Fe—Pt—Ag—C-based sintered compact sputtering target having a composition represented by a formula (Fe_{100-X}—Pt_{X})_{100-Y-Z}—Ag_{Y}—C_{Z} (wherein X represents a numerical value satisfying a formula 35≦X≦55; Y represents a numerical value satisfying a formula 0.5≦Y≦15; and Z represents a numerical value satisfying a formula 15≦Z≦55) when expressed in an atomic ratio, and having a relative density of 93% or more.

In the present invention, the content Z of the C grains in the sputtering target composition is preferably 15 or more and 55 or less in terms of an atomic ratio. When the content Z of the C grains in the target composition is less than 15 in terms of an atomic ratio, there are cases where it is not possible to obtain favorable magnetic properties; and when the content Z of the C grains in the target composition exceeds 55 in terms of an atomic ratio, the C grains become aggregated, and there are cases where the generation of particles will increase.

Moreover, in the present invention, the content X of Pt in the Fe—Pt composition is preferably 35 or more and 55 or less in terms of an atomic ratio. When the content X of Pt in the Fe—Pt composition is less than 35 in terms of an atomic ratio, the FePt phase having an L1₀ structure is no longer generated; and when the content X of Pt in the Fe—Pt composition exceeds 55 in terms of an atomic ratio, the FePt phase having an L1₀ structure is also no longer generated.

The relative density being 93% or more is an important requirement of the present invention. When the relative density is high, the problem of degassing from the sputtering target during sputtering can be minimized, and the adhesion of the alloy and the C grains will improve; therefore, the generation of particles can be effectively inhibited. The relative density is desirably 95% or more.

In the present invention, the term “relative density” refers to the value obtained by dividing the measured density of the target by the calculated density (also known as the theoretical density). The calculated density is the density upon hypothesizing that the constituent elements of the target coexist without mutually diffusing or reacting, and is calculated based on the following formula.

Formula: [calculated density]=Sigma Σ([atomic weight of constituent elements]×[atomic ratio of constituent elements])/Σ([atomic weight of constituent elements]×[atomic ratio of constituent elements]/[literature density of constituent elements])

Here, Σ implies taking the sum of all constituent elements of the target.

The following values are adopted as the density (literature data) of the respective elements.

Fe: 7.86 g/cc, Pt: 21.45 g/cc, Ag: 10.49 g/cc, C: 2.26 g/cc

Moreover, the content Y of Ag in the Fe—Pt—Ag—C-based sintered compact composition is preferably 0.5 or more and 15 or less in terms of an atomic ratio. When the content Y of Ag is less than 0.5 in terms of an atomic ratio, there are cases where it is not possible to sufficiently lower the heat treatment temperature upon causing the deposited magnetic thin film having a granular structure to have an L1₀ structure; and when the content Y of Ag exceeds 15 in terms of an atomic ratio, there are cases where it is not possible to obtain favorable magnetic properties.

Moreover, a significant feature of the Fe—Pt—Ag—C-based sintered compact sputtering target is in that the Fe—Pt—Ag—C-based sintered compact sputtering target has a texture where an Fe—Pt—C phase, in which C is dispersed in an Fe—Pt alloy, and a Ag phase, mutually coexist. In the foregoing case, the Fe—Pt—Ag—C-based sintered compact sputtering target has a texture where an Fe—Pt—C phase, in which C is dispersed in an Fe—Pt alloy, and a Ag—C phase, in which C is dispersed in Ag, mutually coexist, or may have a texture where an Fe—Pt—C phase, in which C is dispersed in an Fe—Pt alloy, a Ag phase, and a Ag—C phase, in which C is dispersed in Ag, mutually coexist. All of the foregoing phase structures are able to cause fine C to be dispersed in the target.

Upon producing this Fe—Pt—Ag—C-based sintered compact sputtering target, the present invention is characterized by producing an Fe—Pt—C sintered compact in advance, pulverizing the sintered compact to produce a pulverized powder, mixing the pulverized powder with a Ag powder, and sintering the resultant mixed powder at a temperature lower than a melting point of Ag.

In other words, the present invention aims to improve the density by preliminarily producing a dense sintered compact based on Fe—Pt—C, which does not contain Ag having a low melting point, and using the pulverized powder of the dense sintered compact.

Conventionally, a mixed powder of the Fe powder, the Pt powder, the Ag powder and the C powder was sintered at a temperature that is lower than the melting point of Ag. Nevertheless, while it is obviously necessary to sinter the raw materials containing the Ag powder at a temperature that is lower than the melting point of Ag, since the melting point of Ag is lower than that of the other materials, there is a problem in that the raw material powders other than the Ag powder are hardly sintered.

Thus, a high-density Fe—Pt—C-based sintered compact is produced in advance by sintering the mixed powder of the Fe powder, the Pt powder and the C powder (excluding Ag) at a temperature that is higher than the melting point of Ag and promotes the sintering. Next, the produced sintered compact is pulverized and sieved to an appropriate grain size, and the resultant Fe—Pt—C powder is mixed with a Ag powder to produce a sintered compact. As a result of adopting the foregoing method, it is possible to obtain a high-density sintered compact having a texture in which Ag is distributed in a manner of connecting the Fe—Pt—C grains to each other.

Here, by adjusting the grain size of the Fe—Pt—C powder and the grain size of the Ag powder to be [Fe—Pt—C powder]>[Ag powder], the density tends to increase more. Furthermore, it is also possible to mix a small amount of C in the Ag powder in order to uniformly distribute C in the Fe—Pt—Ag—C target.

The mixed amount in the foregoing case is preferably adjusted so that the volume ratio of the additive amount of C in Ag is roughly 20% or less. As stated above, an Fe—Pt—C sintered compact is produced in advance, the produced sintered compact is pulverized to obtain a pulverized powder, the obtained pulverized powder is mixed with a Ag powder and a C powder, and thereby it will be possible to sinter the resultant mixed powder at a temperature that is less than the melting point of Ag.

Based on the above, it is possible to produce the unique Fe—Pt—Ag—C-based sintered compact sputtering target described above. In the foregoing case, it is desirable that the density of the pulverized powder of the Fe—Pt—C sintered compact, which is produced in advance, is high; that is, it is desirable that the relative density is 93% or more. It is thereby possible to easily achieve the high densification of the Fe—P—Ag—C-based sintered compact sputtering target as the end product.

Note that oxides of one or more components selected from B, Si, Cr, Ti, Ta, W, Al, Mg, Mn, Ca, Zr, and Y may also be included in an amount of 1 to 20 mol %. These components need to be added within a range that will not considerably affect (lower) the density.

The sputtering target of the present invention is produced via the powder sintering method, and upon producing the sputtering target, respective raw material powders (Fe powder, Pt powder, Ag powder, C powder) are prepared. Desirably, the prepared raw material powders have a grain size of 0.5 μm or more and 10 μm or less. When the grain size of the raw material powders is too small, there is a problem in that oxidation is promoted and the oxygen concentration in the sputtering target will increase. Therefore, the grain size of the raw material powders is desirably 0.5 μm or more.

Meanwhile, when the grain size of the raw material powders is too large, it becomes difficult to finely disperse the C grains in the alloy. Therefore, the grain size of the raw material powders is desirably 10 μm or less.

In addition, an alloy powder (Fe—Pt powder) may be used as the raw material powder. In particular, an alloy powder containing Pt, while this also depends on the composition thereof, is effective for reducing the oxygen content in the raw material powders. Even in cases of using an alloy powder, the grain size thereof is desirably 0.5 μm or more and 10 μm or less.

Subsequently, the foregoing raw material powders (excluding Ag powder) are weighed and mixed using a ball mill or the like, and the obtained mixed powder (mixed powder of Fe powder, Pt powder, and C powder) is molded and sintered via a hot press. In addition to hot press, methods such as the plasma discharge sintering method and the hot isostatic sintering method may also be used. The holding temperature during sintering varies depending on the composition of Fe—Pt—C, but is often within the temperature range of 1200 to 1400° C.

Subsequently, the Fe—Pt—C sintered compact removed from the hot press is subject to hot isostatic pressing. The hot isostatic pressing is effective for increasing the density of the sintered compact. The holding temperature during hot isostatic pressing varies depending on the composition of the sintered compact, but is often within the temperature range of 1200 to 1400° C. Moreover, the applied pressure is set to 100 MPa or more and 200 MPa or less.

The surface portion of the obtained Fe—Pt—C sintered compact is removed with a lathe or the like, and the Fe—Pt—C sintered compact is thereafter pulverized using a pulverizing device such as a jaw crusher, a roll crusher, a Brown mill, or a hammer mill in order to prepare an Fe—Pt—C powder. The grain size of the prepared Fe—Pt—C powder is desirably 20 μm or more and 300 μm or less.

The obtained Fe—Pt—C powder is weighed together with a Ag powder to attain the intended target composition. Here, a C powder may also be added in a small amount. The weighed powders are subsequently mixed using a mixing device such as a mixer.

The resultant mixed powder is molded and sintered via a hot press. In addition to the hot press, methods such as the plasma discharge sintering method and the hot isostatic sintering method may also be used. The holding temperature during sintering is set to a temperature that is lower than the melting point of Ag. In many cases, the temperature range is 900 to 950° C.

Subsequently, the Fe—Pt—Ag—C sintered compact removed from the hot press is subject to hot isostatic pressing. The hot isostatic pressing is effective for increasing the density of the sintered compact. The holding temperature during hot isostatic pressing is set to a temperature that is lower than the melting point of Ag. In many cases, the temperature range is 900 to 950° C. Moreover, the applied pressure is set to 100 MPa or more and 200 MPa or less.

By processing the obtained sintered compact into an intended shape using a lathe, it is possible to produce the sputtering target of the present invention.

It is thereby possible to finely disperse C grains in an alloy, and produce a high-density Fe—Pt—Ag—C-based sputtering target having C grains dispersed therein. The sputtering target of the present invention produced as described above is effective as a sputtering target for use in the deposition of a magnetic thin film having a granular structure.

### EXAMPLES

The present invention is now explained based on the following Examples and Comparative Examples. Note that these Examples are merely illustrative, and the present invention is not limited in any way by these Examples. In other words, the present invention is limited only based on its scope of claims, and the present invention covers various modifications other than the Examples included herein.

### Example 1

As raw material powders, an Fe powder having an average grain size of 3 μm, a Pt powder having an average grain size of 3 μm, a Ag powder having an average grain size of 2 μm, and a C powder having an average grain size of 1 μm were prepared. The Fe powder, the Pt powder and the C powder were foremost weighed to obtain a total weight of 3000 g so as to attain the following atomic ratio.

Atomic ratio: (Fe₅₀—Pt₅₀)_{52.94}—C_{47.06}

Next, the weighed powders were placed in a ball mill pot having a capacity of 10 liters together with zirconia balls as the grinding medium, and mixed and pulverized by being rotated for 4 hours. Subsequently, the mixed powder was removed from the pot and filled in a carbon mold to be subject to molding and sintering with a hot press device. The hot press conditions were a vacuum atmosphere, rate of temperature increase of 300° C./hour, holding temperature of 1400° C., and holding time of 2 hours, and pressure of 30 MPa was applied from the time of starting the temperature increase until the end of the holding time. After the end of holding, the sintered compact was left in the chamber and cooled naturally.

Subsequently, the sintered compact was removed from the carbon mold and subject to hot isostatic pressing. The hot isostatic pressing conditions were rate of temperature increase of 300° C./hour, holding temperature of 1250° C., and holding time of 2 hours, gas pressure of Ar gas was gradually increased from the time of starting the temperature increase, and pressure of 150 MPa was applied during holding at 1250° C. After the end of holding, the sintered compact was left in the furnace and cooled naturally.

The density of the obtained Fe—Pt—C sintered compact was 95.2%. The obtained Fe—Pt—C sintered compact was pulverized using a jaw crusher and a Brown mill. The pulverized powder was additionally sieved using a sieve having a sieve opening of 150 μm, and coarse grains on the sieve were eliminated.

The obtained Fe—Pt—C powder and a Ag powder were weighed to obtain a total weight of 2400 g in order to prepare a sputtering target having the following atomic ratio.

Atomic ratio: (Fe₅₀—Pt₅₀)₄₅—Ag₁₅—C₄₀

Subsequently, the weighed powders were mixed for 10 minutes in a planetary-type mixer having a ball capacity of approximately 7 liters. The mixed powder was removed from the planetary-type mixer and filled in a carbon mold to be subject to molding and sintering with a hot press device. The hot press conditions were a vacuum atmosphere, rate of temperature increase of 300° C./hour, holding temperature of 950° C., and holding time of 2 hours, and pressure of 30 MPa was applied from the time of starting the temperature increase until the end of the holding time. After the end of holding, the sintered compact was left in the chamber and cooled naturally.

Subsequently, the sintered compact was removed from the carbon mold and subject to hot isostatic pressing. The hot isostatic pressing conditions were rate of temperature increase of 300° C./hour, holding temperature of 950° C., and holding time of 2 hours, gas pressure of Ar gas was gradually increased from the time of starting the temperature increase, and pressure of 150 MPa was applied during holding at 950° C. After the end of holding, the sintered compact was left in the furnace and cooled naturally.

The produced sintered compact was cut with a lathe to obtain a sputtering target. As a result of measuring the density of this target based on the Archimedes method and dividing the obtained measured density by the calculated density, the relative density was 94.6%.

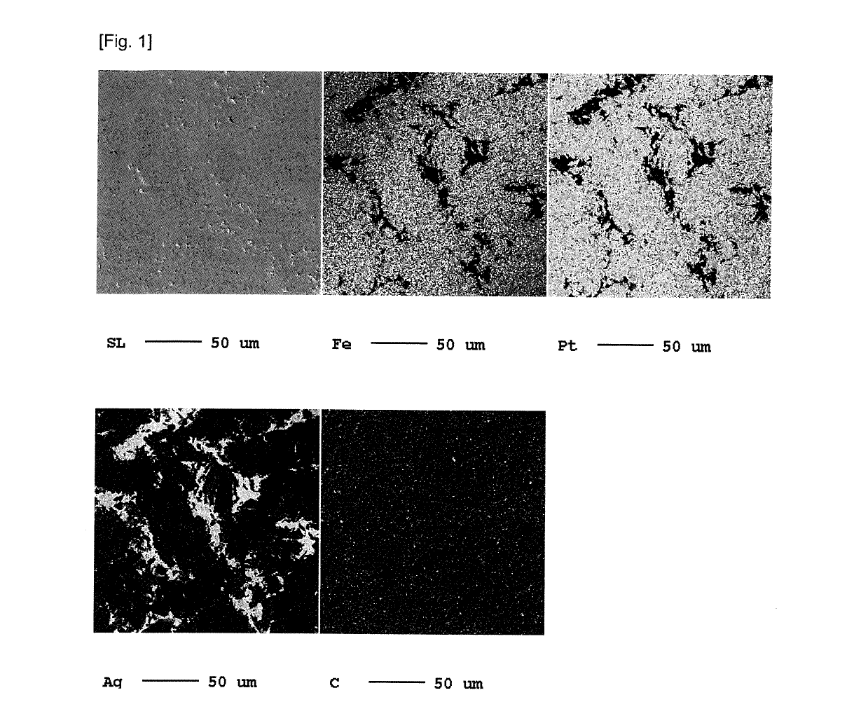

By way of reference, a secondary electron image and an element distribution image upon observing the polished surface of the sputtering target of Example 1 via EPMA is shown in FIG. 1 (the secondary electron image is indicated as SL in the diagram). The finely dispersed matrix in FIG. 1 is the Fe—Pt—C phase. In addition, it is possible to observe that the Ag phase, as relatively large grains, is dispersed like scattered clouds in the matrix of the Fe—Pt—C phase. Moreover, based on FIG. 1, it is possible to confirm that fine C is dispersed in the texture of the target.

Subsequently, the sintered compact was cut with a lathe into a shape having a diameter of 180.0 mm and a thickness of 5.0 mm to obtain a disk-shaped target. The obtained target was mounted on magnetron sputtering equipment (C-3010 sputtering system manufactured by Canon Anelva Corporation) and sputtered. The sputtering conditions were input power of 1 kW and Ar gas pressure of 1.7 Pa, and, after performing pre-sputtering at 2 kWhr, film deposition was performed onto a Si substrate having a diameter of 4 inches for 20 minutes. Subsequently, the number of particles that adhered to the substrate surface was measured using a particle counter. The number of particles in this case was 27.

### Example 2

As raw material powders, an Fe powder having an average grain size of 3 μm, a Pt powder having an average grain size of 3 μm, a Ag powder having an average grain size of 2 μm, and a C powder having an average grain size of 1 μm were prepared. The Fe powder, the Pt powder and the C powder were foremost weighed to obtain a total weight of 3000 g so as to attain the following atomic ratio.

Atomic ratio: (Fe₅₀—Pt₅₀)_{56.25}—C_{43.75}

Next, the weighed powders were placed in a ball mill pot having a capacity of 10 liters together with zirconia balls as the grinding medium, and mixed and pulverized by being rotated for 4 hours. Subsequently, the mixed powder was removed from the pot and filled in a carbon mold to be subject to molding and sintering with a hot press device. The hot press conditions were a vacuum atmosphere, rate of temperature increase of 300° C./hour, holding temperature of 1400° C., and holding time of 2 hours, and pressure of 30 MPa was applied from the time of starting the temperature increase until the end of the holding time. After the end of holding, the sintered compact was left in the chamber and cooled naturally.

Subsequently, the sintered compact was removed from the carbon mold and subject to hot isostatic pressing. The hot isostatic pressing conditions were rate of temperature increase of 300° C./hour, holding temperature of 1250° C., and holding time of 2 hours, gas pressure of Ar gas was gradually increased from the time of starting the temperature increase, and pressure of 150 MPa was applied during holding at 1250° C. After the end of holding, the sintered compact was left in the furnace and cooled naturally.

The density of the obtained Fe—Pt—C sintered compact was 95.9%. The obtained Fe—Pt—C sintered compact was pulverized using a jaw crusher and a Brown mill. The pulverized powder was additionally sieved using a sieve having a sieve opening of 150 μm, and coarse grains on the sieve were eliminated.

The obtained Fe—Pt—C powder, a Ag powder and a C powder were weighed to obtain a total weight of 2400 g in order to prepare a sputtering target having the following atomic ratio.

Atomic ratio: (Fe₅₀—Pt₅₀)₄₅—Ag₁₅—C₄₀

Subsequently, the weighed powders were mixed for 10 minutes in a planetary-type mixer having a ball capacity of approximately 7 liters. The mixed powder was removed from the planetary-type mixer and filled in a carbon mold to be subject to molding and sintering with a hot press device. The hot press conditions were a vacuum atmosphere, rate of temperature increase of 300° C./hour, holding temperature of 950° C., and holding time of 2 hours, and pressure of 30 MPa was applied from the time of starting the temperature increase until the end of the holding time. After the end of holding, the sintered compact was left in the chamber and cooled naturally.

Subsequently, the sintered compact was removed from the carbon mold and subject to hot isostatic pressing. The hot isostatic pressing conditions were rate of temperature increase of 300° C./hour, holding temperature of 950° C., and holding time of 2 hours, gas pressure of Ar gas was gradually increased from the time of starting the temperature increase, and pressure of 150 MPa was applied during holding at 950° C. After the end of holding, the sintered compact was left in the furnace and cooled naturally.

The produced sintered compact was cut with a lathe to obtain a sputtering target. As a result of measuring the density of this target based on the Archimedes method and dividing the obtained measured density by the calculated density, the relative density was 93.4%. Moreover, upon observing the polished surface of the sputtering target of Example 2 via EPMA, the sputtering target had a texture where an Fe—Pt—C phase and a Ag—C phase mutually coexist.

Subsequently, the sintered compact was cut with a lathe into a shape having a diameter of 180.0 mm and a thickness of 5.0 mm to obtain a disk-shaped target. The obtained target was mounted on magnetron sputtering equipment and sputtered according to the same conditions as Example 1. Consequently, the number of particles was 36.

### Comparative Example 1

As raw material powders, an Fe powder having an average grain size of 3 μm, a Pt powder having an average grain size of 3 μm, a Ag powder having an average grain size of 2 μm, and a C powder having an average grain size of 1 μm were prepared. Subsequently, the prepared powders were weighed to obtain a total weight of 2400 g so as to attain the following atomic ratio.

Atomic ratio: (Fe₅₀—Pt₅₀)₄₅—Ag₁₅—C₄₀

Next, the weighed powders were placed in a ball mill pot having a capacity of 10 liters together with zirconia balls as the grinding medium, and mixed and pulverized by being rotated for 4 hours. Subsequently, the mixed powder was removed from the pot and filled in a carbon mold to be subject to molding and sintering with a hot press device. The hot press conditions were a vacuum atmosphere, rate of temperature increase of 300° C./hour, holding temperature of 950° C., and holding time of 2 hours, and pressure of 30 MPa was applied from the time of starting the temperature increase until the end of the holding time. After the end of holding, the sintered compact was left in the chamber and cooled naturally.

Subsequently, the sintered compact was removed from the carbon mold and subject to hot isostatic pressing. The hot isostatic pressing conditions were rate of temperature increase of 300° C./hour, holding temperature of 950° C., and holding time of 2 hours, gas pressure of Ar gas was gradually increased from the time of starting the temperature increase, and pressure of 150 MPa was applied during holding at 950° C. After the end of holding, the sintered compact was left in the furnace and cooled naturally.

The obtained sintered compact was cut with a lathe to obtain a sputtering target. As a result of measuring the density of this target based on the Archimedes method and dividing the obtained measured density by the calculated density, the relative density was 92.7%, which was lower than the density of Example 1 and the density of Example 2. Moreover, upon observing the polished surface of the sputtering target of Comparative Example 1 via EPMA, the sputtering target had a texture where C and Ag were dispersed in an Fe—Pt alloy.

Subsequently, the sintered compact was cut with a lathe into a shape having a diameter of 180.0 mm and a thickness of 5.0 mm to obtain a disk-shaped target. The obtained target was mounted on magnetron sputtering equipment and sputtered according to the same conditions as Example 1. Consequently, the number of particles was 73, which increased in comparison to Example 1 and Example 2.

### Example 3

As raw material powders, an Fe powder having an average grain size of 3 μm, a Pt powder having an average grain size of 3 μm, a Ag powder having an average grain size of 2 μm, and a C powder having an average grain size of 1 μm were prepared. The Fe powder, the Pt powder and the C powder were foremost weighed to obtain a total weight of 3000 g so as to attain the following atomic ratio.

Atomic ratio: (Fe₆₅—Pt₃₅)_{42.11}—C_{57.89}

Next, the weighed powders were placed in a ball mill pot having a capacity of 10 liters together with zirconia balls as the grinding medium, and mixed and pulverized by being rotated for 4 hours. Subsequently, the mixed powder was removed from the pot and filled in a carbon mold to be subject to molding and sintering with a hot press device. The hot press conditions were a vacuum atmosphere, rate of temperature increase of 300° C./hour, holding temperature of 1400° C., and holding time of 2 hours, and pressure of 30 MPa was applied from the time of starting the temperature increase until the end of the holding time. After the end of holding, the sintered compact was left in the chamber and cooled naturally.

Subsequently, the sintered compact was removed from the carbon mold and subject to hot isostatic pressing. The hot isostatic pressing conditions were rate of temperature increase of 300° C./hour, holding temperature of 1350° C., and holding time of 2 hours, gas pressure of Ar gas was gradually increased from the time of starting the temperature increase, and pressure of 150 MPa was applied during holding at 1350° C. After the end of holding, the sintered compact was left in the furnace and cooled naturally.

The density of the obtained Fe—Pt—C sintered compact was 95.1%. The obtained Fe—Pt—C sintered compact was pulverized using a jaw crusher and a Brown mill. The pulverized powder was additionally sieved using a sieve having a sieve opening of 106 μm, and coarse grains on the sieve were eliminated.

The obtained Fe—Pt—C powder, a Ag powder and a C powder were weighed to obtain a total weight of 2100 g in order to prepare a sputtering target having the following atomic ratio.

Atomic ratio: (Fe₆₅—Pt₃₅)₄₀—Ag₅—C₅₅

Subsequently, the weighed powders were mixed for 10 minutes in a planetary-type mixer having a ball capacity of approximately 7 liters. The mixed powder was removed from the planetary-type mixer and filled in a carbon mold to be subject to molding and sintering with a hot press device. The hot press conditions were a vacuum atmosphere, rate of temperature increase of 300° C./hour, holding temperature of 900° C., and holding time of 2 hours, and pressure of 30 MPa was applied from the time of starting the temperature increase until the end of the holding time. After the end of holding, the sintered compact was left in the chamber and cooled naturally.

Subsequently, the sintered compact was removed from the carbon mold and subject to hot isostatic pressing. The hot isostatic pressing conditions were rate of temperature increase of 300° C./hour, holding temperature of 900° C., and holding time of 2 hours, gas pressure of Ar gas was gradually increased from the time of starting the temperature increase, and pressure of 150 MPa was applied during holding at 900° C. After the end of holding, the sintered compact was left in the furnace and cooled naturally.

The produced sintered compact was cut with a lathe to obtain a sputtering target. As a result of measuring the density of this target based on the Archimedes method and dividing the obtained measured density by the calculated density, the relative density was 93.8%. Moreover, upon observing the polished surface of the sputtering target of Example 3 via EPMA, the sputtering target had a texture where an Fe—Pt—C phase and a Ag phase mutually coexist.

Subsequently, the sintered compact was cut with a lathe into a shape having a diameter of 180.0 mm and a thickness of 5.0 mm to obtain a disk-shaped target. The obtained target was mounted on magnetron sputtering equipment and sputtered. Consequently, the number of particles was 38.

### Comparative Example 2

As raw material powders, an Fe powder having an average grain size of 3 μm, a Pt powder having an average grain size of 3 μm, a Ag powder having an average grain size of 2 μm, and a C powder having an average grain size of 1 μm were prepared. Subsequently, the prepared powders were weighed to obtain a total weight of 2100 g so as to attain the following atomic ratio.

Atomic ratio: (Fe₆₅—Pt₃₅)₄₀—Ag₅—C₅₅

Next, the weighed powders were placed in a ball mill pot having a capacity of 10 liters together with zirconia balls as the grinding medium, and mixed and pulverized by being rotated for 4 hours. Subsequently, the mixed powder was removed from the pot and filled in a carbon mold to be subject to molding and sintering with a hot press device. The hot press conditions were a vacuum atmosphere, rate of temperature increase of 300° C./hour, holding temperature of 900° C., and holding time of 2 hours, and pressure of 30 MPa was applied from the time of starting the temperature increase until the end of the holding time. After the end of holding, the sintered compact was left in the chamber and cooled naturally.

Subsequently, the sintered compact was removed from the carbon mold and subject to hot isostatic pressing. The hot isostatic pressing conditions were rate of temperature increase of 300° C./hour, holding temperature of 900° C., and holding time of 2 hours, gas pressure of Ar gas was gradually increased from the time of starting the temperature increase, and pressure of 150 MPa was applied during holding at 900° C. After the end of holding, the sintered compact was left in the furnace and cooled naturally.

The obtained sintered compact was cut with a lathe to obtain a sputtering target. As a result of measuring the density of this target based on the Archimedes method and dividing the obtained measured density by the calculated density, the relative density was 88.9%, which was lower than the density of Example 3. Moreover, upon observing the polished surface of the sputtering target of Comparative Example 2 via EPMA, the sputtering target had a texture where C and Ag were dispersed in an Fe—Pt alloy.

Subsequently, the sintered compact was cut with a lathe into a shape having a diameter of 180.0 mm and a thickness of 5.0 mm to obtain a disk-shaped target. The obtained target was mounted on magnetron sputtering equipment and sputtered according to the same conditions as Example 3. Consequently, the number of particles was 92, which increased in comparison to Example 3.

### INDUSTRIAL APPLICABILITY

The present invention yields a superior effect of being able to provide a high-density Fe—Pt-based sputtering target having C grains dispersed therein which enables the deposition of a magnetic thin film having a granular structure without the use of expensive co-sputtering equipment, and which also enables the reduction in the amount of particles generated during sputtering. Accordingly, the present invention is useful as a sputtering target for use in depositing a magnetic thin film having a granular structure.

1: An Fe—Pt—Ag—C-based sintered compact sputtering target having a composition represented by a formula (Fe_{100-X}—Pt_{X})_{100-Y-Z}—Ag_{Y}—C_{Z}, wherein X represents a numerical value satisfying a formula 35≦X≦55; Y represents a numerical value satisfying a formula 0.5≦Y≦15; and Z represents a numerical value satisfying a formula 15≦Z≦55 when expressed in an atomic ratio, and having a relative density of 93% or more.

2: The Fe—Pt—Ag—C-based sintered compact sputtering target according to claim 1, wherein the Fe—Pt—Ag—C-based sintered compact sputtering target has a texture where an Fe—Pt—C phase, in which C is dispersed in an Fe—Pt alloy, and a Ag phase, mutually coexist.

3: The Fe—Pt—Ag—C-based sintered compact sputtering target according to claim 1, wherein the Fe—Pt—Ag—C-based sintered compact sputtering target has a texture where an Fe—Pt—C phase, in which C is dispersed in an Fe—Pt alloy, and a Ag—C phase, in which C is dispersed in Ag, mutually coexist.

4: The Fe—Pt—Ag—C-based sintered compact sputtering target according to claim 1, wherein the Fe—Pt—Ag—C-based sintered compact sputtering target has a texture where an Fe—Pt—C phase, in which C is dispersed in an Fe—Pt alloy, a Ag phase, and a Ag—C phase, in which C is dispersed in Ag, mutually coexist.

5: A method for producing an Fe—Pt—Ag—C-based sintered compact sputtering target, characterized in that an Fe—Pt—C sintered compact is produced in advance, the sintered compact is pulverized to produce a pulverized powder, the pulverized powder is mixed with a Ag powder, and the resultant mixed powder is subject to sintering at a temperature lower than a melting point of Ag.

6: A method for producing an Fe—Pt—Ag—C-based sintered compact sputtering target according to claim 5, wherein the sputtering target has a composition represented by a formula (Fe_{100-X}—Pt_{X})_{100-Y-Z}—Ag_{Y}—C_{Z}, wherein X represents a numerical value satisfying a formula 35≦X≦55; Y represents a numerical value satisfying a formula 0.5≦Y≦15; and Z represents a numerical value satisfying a formula 15≦Z≦55 when expressed in an atomic ratio, and wherein the sputtering target has a relative density of 93% or more.

7: A method for producing an Fe—Pt—Ag—C-based sintered compact sputtering target, characterized in that an Fe—Pt—C sintered compact is produced in advance, the sintered compact is pulverized to produce a pulverized powder, the pulverized powder is mixed with a Ag powder and a C powder, and the resultant mixed powder is subject to sintering at a temperature lower than a melting point of Ag.

8: A method for producing an Fe—Pt—Ag—C-based sintered compact sputtering target according to claim 7, wherein the sputtering target has a composition represented by a formula (Fe_{100-X}—Pt_{X})_{100-Y-Z}—Ag_{Y}—C_{X}, wherein X represents a numerical value satisfying a formula 35≦X≦55; Y represents a numerical value satisfying a formula 0.5≦Y≦15; and Z represents a numerical value satisfying a formula 15≦Z≦55 when expressed in an atomic ratio, and wherein the sputtering target has a relative density of 93% or more.

9: The method for producing an Fe—Pt—Ag—C-based sintered compact sputtering target according to claim 8, characterized in that a pulverized powder of an Fe—Pt—C sintered compact having a relative density of 93% or more is subject to mixing and sintering.

10: The method according to claim 8, wherein the Fe—Pt—Ag—C-based sintered compact sputtering target is produced with a texture where an Fe—Pt—C phase, in which C is dispersed in an Fe—Pt alloy, and a Ag—C phase, in which C is dispersed in Ag, mutually coexist.

11: The method according to claim 10, characterized in that a pulverized powder of an Fe—Pt—C sintered compact having a relative density of 93% or more is subject to mixing and sintering.

12: The method according to claim 8, wherein the Fe—Pt—Ag—C-based sintered compact sputtering target is produced with a texture where an Fe—Pt—C phase, in which C is dispersed in an Fe—Pt alloy, a Ag phase, and a Ag—C phase, in which C is dispersed in Ag, mutually coexist.

13: The method according to claim 12, characterized in that a pulverized powder of an Fe—Pt—C sintered compact having a relative density of 93% or more is subject to mixing and sintering.

14: The method according to claim 7, characterized in that a pulverized powder of an Fe—Pt—C sintered compact having a relative density of 93% or more is subject to mixing and sintering.

15: The method according to claim 6, wherein the Fe—Pt—Ag—C-based sintered compact sputtering target is produced having a texture where an Fe—Pt—C phase, in which C is dispersed in an Fe—Pt alloy, and a Ag phase, mutually coexist.

16: The method according to claim 15, characterized in that a pulverized powder of an Fe—Pt—C sintered compact having a relative density of 93% or more is subject to mixing and sintering.

17: The method according to claim 5, characterized in that a pulverized powder of an Fe—Pt—C sintered compact having a relative density of 93% or more is subject to mixing and sintering.
